(19) United States
(12) Patent Application Publication
(10) Pub. No.: US 2024/0349512 A1
(43) Pub. Date: Oct. 17, 2024

(54) RANDOM ACCESS MEMORY AND METHOD OF FABRICATING THE SAME

(71) Applicant: SEOUL NATIONAL UNIVERSITY R&DB FOUNDATION, Seoul (KR)

(72) Inventors: Jae-Joon KIM, Seoul (KR); Munhyeon KIM, Seoul (KR)

(73) Assignee: SEOUL NATIONAL UNIVERSITY R&DB FOUNDATION, Seoul (KR)

(21) Appl. No.: 18/635,072

(22) Filed: Apr. 15, 2024

(30) Foreign Application Priority Data
Apr. 14, 2023 (KR) 10-2023-0049246

(51) Int. Cl. H10B 53/30

(52) U.S. Cl. CPC H10B 53/30

(57) ABSTRACT

A memory using ferroelectric metal field-effect transistors includes a drain, a source, and a gate formed on a substrate, a gate contact formed on an upper portion of the gate, and a ferroelectric layer disposed between the gate contact and the gate and configured to surround the gate contact, wherein the gate, the ferroelectric layer, and the gate contact operate as a capacitor having a metal-ferroelectric layer-metal (MFM) structure.

### FIELD OF THE INVENTION

The present disclosure relates to a memory using a ferroelectric metal field effect transistor (FeMFET) and a method of fabricating the memory cell.

### BACKGROUND

Research is underway on next-generation non-volatile memory devices. Among next-generation non-volatile memory devices, a ferroelectric field-effect-transistor (FeFET) using ferroelectrics is known to have a very high commercialization potential in that the FeFET uses a material, such as hafnium (Hf) or zirconium (Zr), which is a proven material in the industry. Also, the FeFET is known to be most compatible with the existing a complementary metal oxide semiconductor (CMOS) process. Several ferroelectric materials are being studied, and among the ferroelectric materials, HZO, which is based on HfO₂ and injected with Zr, is evaluated as having the highest potential for commercialization.

The conventional FeFET has a large channel area, which increases the entire area of a memory cell, and thereby, an area ratio may be adjusted by reducing chip density. In order to solve the problem, research has been conducted to reduce an area of an FET by using a metal-ferroelectric layer-metal (MFM) structure for connection of metal-ferroelectric-metal and performing the connection of metal-ferroelectric-metal at a back-end-of-line (BEOL) process, but there is a problem in that additional lithography processes are required and manufacturing costs of memory cells increase, and the difficulty in controlling the area ratio increases.

In order to fabricate a FeFET-based memory, the present disclosure proposes a FeMFET having a new structure that may improve the performance and integration of a device and proposes a memory using the FeMFET. In particular, the FeMFET uses the MFM structure in a front-end-of-line (FEOL) process and also may effectively adjust a ratio of the MOSFET channel to a ferroelectric area.

### PATENT PRIOR ART

An example of the related art includes U.S. Patent Publication No. 2002-0359548 (Title of invention: Semiconductor structure having memory device and method of forming the same).

### CONTENTS OF THE DISCLOSURE

### The Problem Trying to Solve

The present disclosure provides a memory using a ferroelectric metal field effect transistor that may adjust a ratio of an area of a ferroelectric layer to a channel of a FET and a method of fabricating the memory.

However, technical problems of the present embodiment are not limited to the technical problem described above, and other technical problems may exist.

### Means of Solving the Problem

According to an aspect of the present disclosure, a memory using ferroelectric metal field-effect transistors includes a drain, a source, and a gate formed on a substrate, a gate contact formed on an upper portion of the gate, and a ferroelectric layer disposed between the gate contact and the gate and configured to surround the gate contact, wherein the gate, the ferroelectric layer, and the gate contact operate as a capacitor having a metal-ferroelectric layer-metal (MFM) structure.

According to another aspect of the present disclosure, a method of fabricating a memory using a ferroelectric metal field effect transistor includes forming a drain, a source, and a gate on a substrate, forming a gate contact region on an upper portion of the gate, and sequentially forming a ferroelectric layer and a gate contact in the gate contact region, wherein the gate, the ferroelectric layer, and the gate contact operate as a capacitor having a metal-ferroelectric layer-metal (MFM) structure.

### Effects of the Invention

According to the configuration of the present disclosure, a gate contact and a ferroelectric layer are formed in the front-end-of-line (FEOL) process, and thus, a ratio between areas facing a gate, the ferroelectric layer, and the gate contact may be effectively adjusted. Through this, characteristics of the memory using a ferroelectric metal field effect transistor may be optimized.

In addition, when it is necessary to adjust the area ratio in each process, especially when it is necessary to increase the area of the ferroelectric layer, the area ratio may be easily adjusted by adjusting a penetration depth of the gate contact in a state where a cell area is fixed.

### BRIEF DESCRIPTION OF THE DRAWINGS

FIG. 1 illustrates a circuit diagram of a memory cell according to an embodiment;

FIG. 2 illustrates a three-dimensional structure of a memory cell according to an embodiment;

FIGS. 3, and 4 illustrate cross-sectional structures of a memory cell according to an embodiment;

FIG. 5 is a flowchart illustrating a method of fabricating a memory cell, according to an embodiment;

FIGS. 6, and 7 are views illustrating a method of fabricating a memory, according to an embodiment;

FIG. 8 illustrates cross-sectional structures of a memory cell according to another embodiment; and

FIG. 9 is diagrams illustrating configurations of a memory array using a ferroelectric metal field effect transistor according to the present disclosure.

### DETAILED DESCRIPTION OF THE EMBODIMENTS

Hereinafter, embodiments of the present disclosure will be described in detail such that those skilled in the art to which the present disclosure belongs may easily implement the present disclosure with reference to the accompanying drawings. However, the present disclosure may be implemented in many different forms and is not limited to the embodiments to be described herein. In addition, in order to clearly describe the present disclosure with reference to the drawings, portions irrelevant to the description are omitted, and similar reference numerals are attached to similar portions throughout the specification.

When it is described that a portion is “connected” to another portion throughout the specification, this includes not only a case where the portion is “directly connected” to another portion but also a case where the portion is “indirectly connected” to another portion with another component therebetween. In addition, when it is described that a portion “includes” a certain component, this means that the portion may further include another component without excluding another component unless otherwise stated.

Throughout the specification of the present application, when a member is described to be located on another member, this includes not only ae case where a member is in contact with another member, but also a case where another member exists between the two members.

Hereinafter, preferred embodiments of the present disclosure will be described in detail with reference to the accompanying drawings and the following description. However, the present disclosure is not limited to the embodiments described herein and may be embodied in other forms. Like reference numerals refer to like elements throughout the specification.

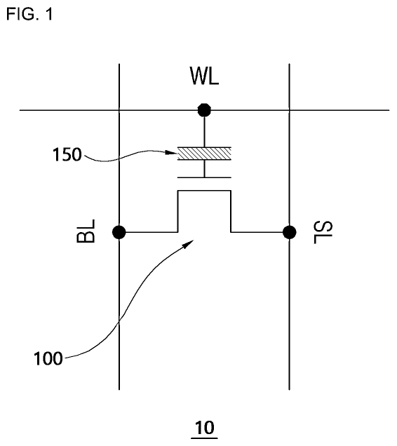

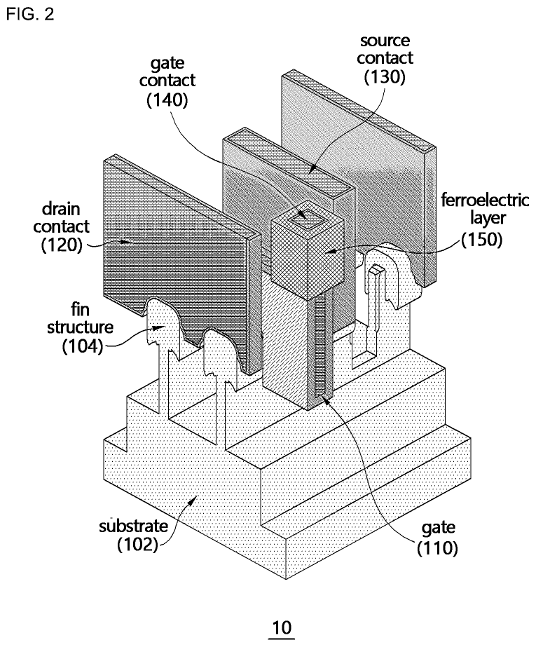

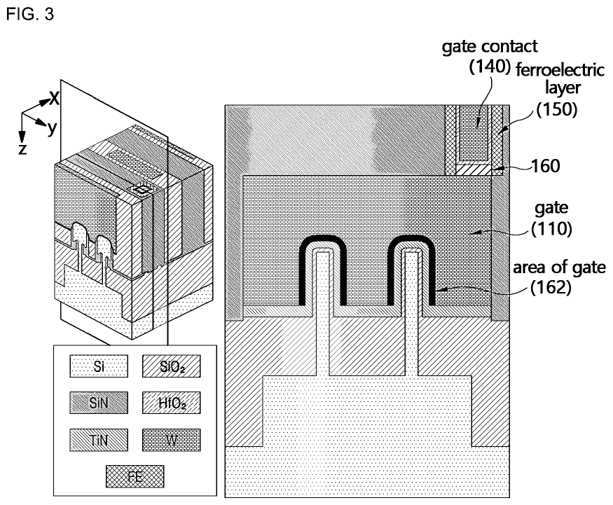

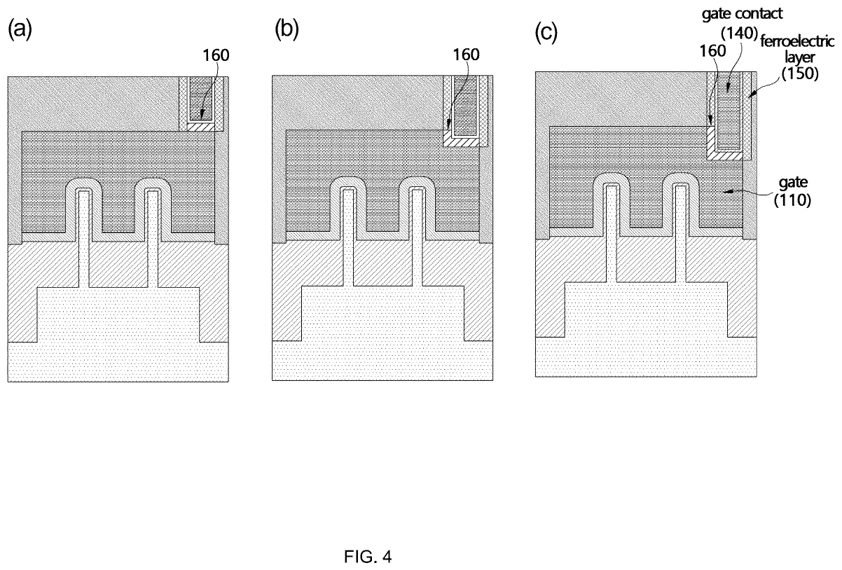

FIG. 1 illustrates a circuit diagram of a memory cell according to an embodiment, FIG. 2 illustrates a three-dimensional structure of a memory cell according to an embodiment, and FIGS. 3, and 4 illustrate cross-sectional structures of a memory cell according to an embodiment.

As illustrated in FIGS. 1 and 2, a memory 10 of the present disclosure is formed based on a ferroelectric metal field effect transistor (FeMFET) 100. The ferroelectric metal field effect transistor 100 includes a drain, a source, and a gate 110 formed on a substrate, a gate contact 140 formed on an upper portion of the gate 110, and a ferroelectric layer 150 disposed between the gate contact 140 and the gate 110 to surround the gate contact 140. In addition, the gate contact 140 is connected to a word line WL, a bit line BL is connected to the drain, and a source line SL is connected to the source. A structure in which the word line WL is connected only to the gate contact 140, and the word line WL receives both a read signal and a write signal. In particular, during a write operation, an input voltage is divided according to areas, dielectric constants, and thicknesses of the ferroelectric layer 150 and interlayer (IL)/high-K (HK), and accordingly, when the ferroelectric metal field effect transistor 100 according to the present disclosure is used, the same write voltage is applied to the ferroelectric metal field effect transistor 100, and thereby, memory performance may be greatly improved.

With this configuration, the gate 110, the ferroelectric layer 150, and the gate contact 140 operate as a capacitor having a metal-ferroelectric layer-metal (MFM) structure.

The ferroelectric layer 150 may be formed of HZO into which Zr is injected based on HfO₂, HfO₂doped with Al, HfO₂doped with Si, HfO₂, BaTiO₃, PbTiO₃, or so on.

The ferroelectric metal field effect transistor 100 may use a structure of a general field effect transistor (FET), and although a FinFET structure is illustrated in the drawings as an example, a planar FET, a gate all around (GAA)-FET, a nanosheet (NS)-FET, a nanowire (NW)-FET, or a negative capacitance (NC)-FET may also be used as the ferroelectric metal field effect transistor 100:

The FinFET illustrated in FIG. 2 has a structure in which a fin structure 104 extends in one direction on a substrate and the gate 110 is formed to surround the fin structure 104 in a shape of crossing the fin structure 104.

A detailed configuration of the memory 10 will be described with reference to FIGS. 3 to 4.

FIGS. 3 to 4 illustrate cross sections that are perpendicular to the X axis and divide the gate 110, the gate contact 140, and the ferroelectric layer 150.

The gate 110 extends in a longitudinal direction (for example, a Y-axis direction), and the gate contact 140 extends from an upper portion of one end of the gate 110 toward the gate 110 in a depth direction (for example, a Z-axis direction).

According to the present disclosure, characteristics of a memory device may be improved by adjusting a ratio between an area 162 of the gate 110 surrounding the fin structure 104 to an area 160 between the gate 110 and the gate contact 140. the area 160 and the area 162 are added for the sake of convenience of description. For example, the area 162 of the gate 110 is calculated by multiplying a width of a channel by a length of the channel, and in the FinFET, the area 162 may be calculated by additionally multiplying the number of fins.

In addition, as illustrated in FIG. 4, the area 160 between the gate 110 and the gate contact 140 may be adjusted according to a depth of the gate contact 140 extending toward the gate 110. As illustrated in FIG. 4A, when the gate contact 140 extends to an upper portion of the gate 110, the area 160 between the gate contact 140 and the gate 110 is a two-dimensional plane, but as illustrated in FIG. 4B or FIG. 4C, when an extension length of the gate contact 140 is lengthened to penetrate into a partial region of the gate 110, facing areas are formed in a three-dimensional shape. That is, a lower surface of the gate contact 140 and a side surface of the gate contact 140 face the gate 110. In this way, it can be seen that, as the gate contact 140 is formed to be deeper toward the gate 110, the area 160 facing the gate 110 and the gate contact 140 increases.

In the present disclosure, the gate contact 140 and the ferroelectric layer 150 are formed in a front-end-of-line (FEOL) process, and thus, a ratio between areas, with which the gate 110, the ferroelectric layer 150, and the gate contact 140 face each other, may be effectively adjusted.

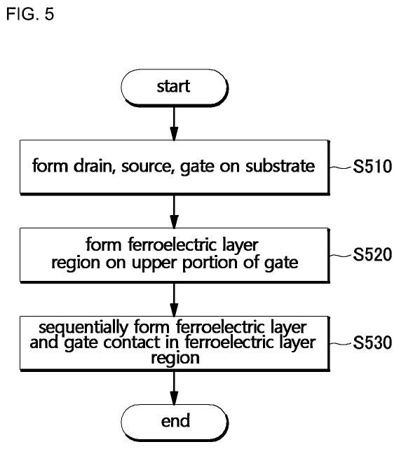

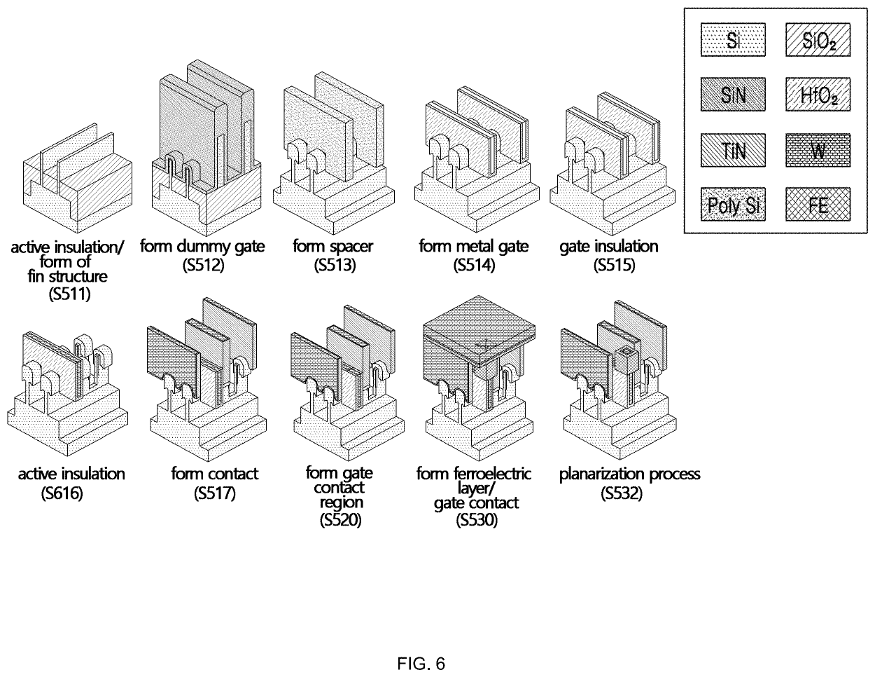

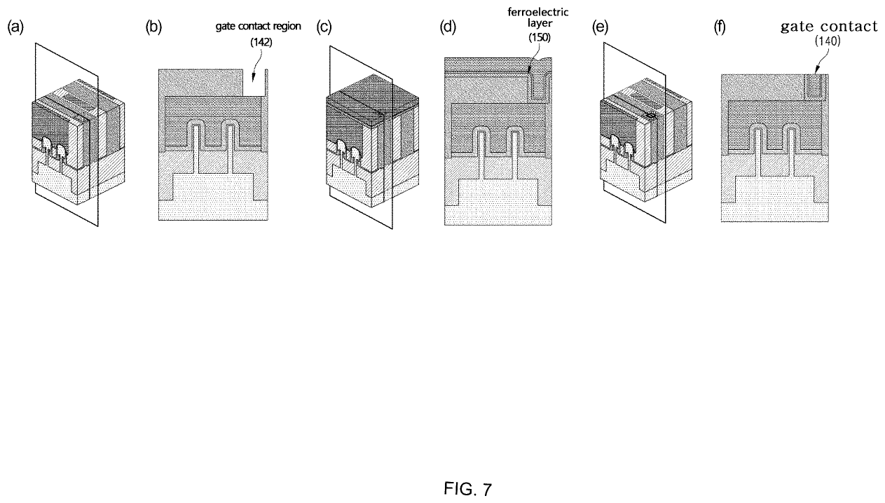

FIG. 5 is a flowchart illustrating a method of fabricating a memory, according to an embodiment, and FIGS. 6, and 7 illustrate the method of fabricating the memory, according to the embodiment.

First, a drain, a source, and a gate are formed on a substrate (S510).

Referring to FIG. 6 for a detailed process, an active region, in which a transistor is formed on a substrate, is formed, and the region is divided for each unit cell, and in which case, a fin structure may be formed during formation of the active region (S511). In addition, forming dummy gates on the active region (S512), forming a spacer between the dummy gates and performing a planarization process (S513), and removing the dummy gates, forming a metal gate in the space where the dummy gates are removed, and removing the spacer (S514). In this case, atomic layer deposition may be used to form the spacer, and the spacer may be formed of a material, such as SiON, SiOCN, or SiOC. Also, a metal gate process may form SiO₂ and deposit a high dielectric material, such as HfO₂, through an interlayer (IL) process. Additionally, for work function engineering, a material, such as Al₂O₃ or La₂O₃, may be stacked as a stacked structure. Also, TiN, AI, TiAlC, TiAl, W, or so on may be used as a material for a metal gate. For example, a work function of the gate 110 may be adjusted by stacking a TiN layer between the gate 110 and the fin structure 104 and using W for the gate 110.

In addition, the metal gate extends in one direction.

Next, the gate 110 is insulated (S515), a gate region is opened and etched, and after etching, an insulating material is deposited, and in this case, SiN may generally be used as the insulating material. Thereafter, a single diffusion break (SDB) process may be used to electrically insulate a source and a drain of a single cell. In this process, an adjacent gate between cells are etched and filled with an insulator.

Thereafter, the active region is insulated (S516), and contacts connected to upper portions of the gate and source are formed (S517).

Next, a gate contact region 142 is formed on an upper portion of the gate 110 (S520). To this end, the gate contact region 142 of a square shape in a region corresponding to the gate 110 in the upper portion is patterned, and etching is performed to a predetermined depth, and thereby, the gate contact region 142 is formed. As illustrated in FIGS. 7A and 7B, the gate contact region 142 is formed on an upper portion of the gate 110. In this case, a lower area of the gate contact region 142 is a portion facing the gate 110 and is formed to be greater than the area with which the gate contact 140 faces the gate 110.

Next, the ferroelectric layer 150 and the gate contact 140 are sequentially formed in the gate contact region 142 (S530).

First, in a state where the gate contact region 142 is formed, the ferroelectric layer is also stacked inside the gate contact region 142 by sequentially stacking the ferroelectric layer 150 and the gate contact 140 on the upper portion, as illustrated in FIGS. 7C and 7D.

Thereafter, a planarization process is performed on the ferroelectric layer 150 and the gate contact 140 to form a shape in which the ferroelectric layer 150 surrounds the gate contact 140 as illustrated in FIGS. 7E and 7F.

In addition, a backend-of-line (BEOL) process is performed to form vias to connect respective contacts to each other and to form word lines and bit lines. In addition, both a single damascene process and a dual damascene process may be used to form the bit lines and so on. The metal material includes Cu, an electro plate process is used therefor, and Ru, Ti, or TiN may be used for a Cu liner.

According to the configuration of the present disclosure, a gate contact and a ferroelectric layer are formed in the front-end-of-line (FEOL) process, and thus, a ratio between areas with which a gate, the ferroelectric layer, and the gate contact face each other may be effectively adjusted. Through this, characteristics of a memory device using a ferroelectric metal field effect transistor may be improved.

Also, when it is necessary to adjust an area ratio in each process, especially when it is necessary to increase an area of a ferroelectric layer, the area ratio may be easily adjusted by adjusting a penetration depth of a gate contact in a state where a cell area is fixed.

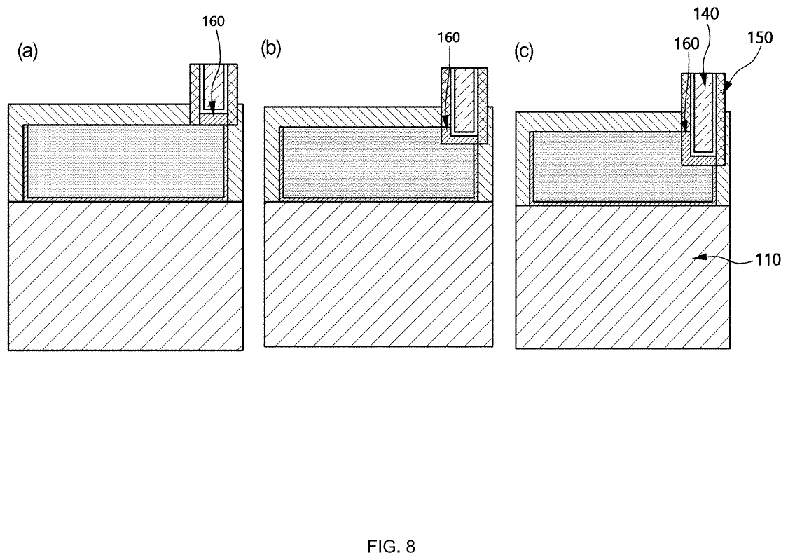

FIG. 8 illustrates cross-sectional structures of a memory cell according to another embodiment.

Unlike the embodiment of FIG. 2, FIGS. 8A to 8C illustrate cases where characteristics of the present disclosure are applied to a planar semiconductor. That is, unlike a three-dimensional semiconductor, the present disclosure may also be applied to a planar semiconductor in which a source, a drain, and a channel layer are formed on the same plane, and the gate is formed on an upper portion of the channel layer. A gate 110 may be formed on an upper portion of a substrate or a semiconductor layer, and a gate contact 140 and a ferroelectric layer 150 may be on an upper portion of the gate 110.

FIG. 8 illustrates cross-sections perpendicular to the X axis, the gate 110 extends in a longitudinal direction (for example, a Y-axis direction), and the gate contact 140 extends from an upper portion of one end of the gate 110 toward the gate 110 in a depth direction (for example, a Z-axis direction).

An area with which the gate 110 faces the gate contact 140 may be adjusted according to a depth in which the gate contact 140 extends toward the gate 110. As illustrated in FIG. 8A, when the gate contact 140 extends to the upper portion of the gate 110, an area with which the gate contact 140 faces the gate 110 is a two-dimensional plane, but as illustrated in FIG. 8B or FIG. 8C, when an extension length of the gate contact 140 is lengthened to penetrate into a partial region of the gate 110, facing areas are formed in a three-dimensional shape. That is, a lower surface of the gate contact 140 and a side surface of the gate contact 140 face the gate 110. In this way, it can be seen that, as the gate contact 140 is formed to be deeper toward the gate 110, the area with which the gate 110 faces the gate contact 140 increases.

In the present disclosure, the gate contact 140 and the ferroelectric layer 150 are formed in the front-end-of-line (FEOL) process, and thus, a ratio between areas, with which the gate 110, the ferroelectric layer 150, and the gate contact 140 face each other, may be effectively adjusted.

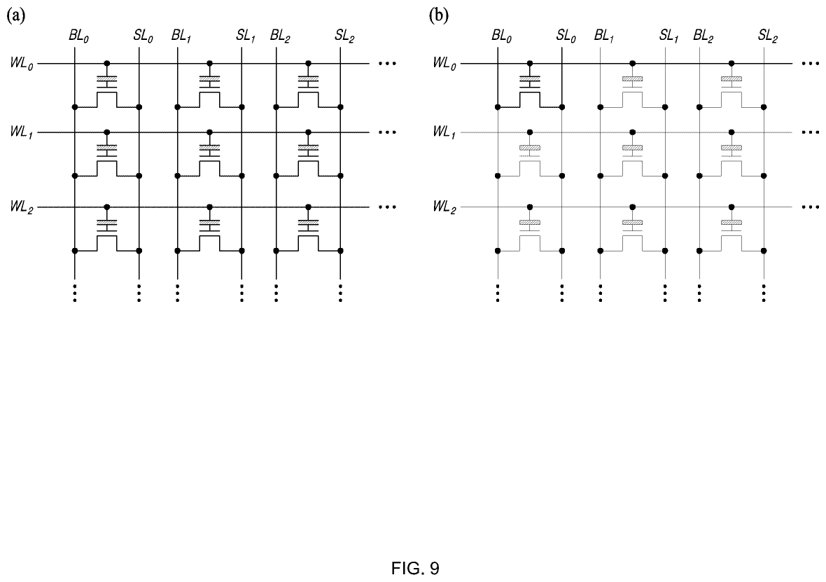

FIG. 9 is diagrams illustrating configurations of a memory array using a ferroelectric metal field effect transistor according to the present disclosure.

The memory of the present disclosure has a 1T structure memory that uses only one transistor and uses a ferroelectric material with a high dielectric constant, thereby having robust characteristics even against an off-current. Accordingly, as illustrated in FIG. 9A, even when memory cells are used in a form of a memory array, an AND type memory array may be configured.

Also, during a write operation, an input voltage is divided according to areas, dielectric constants, and thicknesses of a ferroelectric layer and an IL/HK, and accordingly, when the ferroelectric metal field effect transistor according to the present disclosure is used, the same write voltage is applied to the ferroelectric metal field effect transistor, and thereby, memory performance may be greatly improved.

The write operation is performed with a higher voltage than a read operation, and writing is performed in general by applying a high voltage of 2 V to 4 V to a selected word line. In addition, 0 V is applied to the source line SL and the bit line BL to maximize a polarization phenomenon of the ferroelectric layer (FE).

The read operation is performed by applying a voltage of about 1 V to a selected word line, and the voltage applied to a bit line BL to which a drain is connected has a trade-off relationship with the performance of a device, and in general, increasing the voltage may increase a read speed, but energy efficiency may be reduced and variability issues may be highlighted.

As illustrated in FIG. 9B, when a write operation is performed on a selected memory cell, a write voltage is applied to a word line WL0, and 0 V is applied to the other unselected word lines. 0 V is applied to a bit line BL0 and a source line SL0 connected to the selected memory cell, but a write protection voltage higher than 0 V is applied to the other unselected bit lines and source lines to prevent data from being written by the write voltage. When the write protection voltage is applied, partial polarization may occur, and accordingly, the margin for a memory window (MW) may be reduced. In the present disclosure, an area ratio may be easily adjusted by adjusting a penetration depth of a gate contact in a state where a cell area is fixed, and thereby, a memory window may be greatly increased.

The memory of the present disclosure may be used in various forms. There is a possibility of application as an advanced cell in dynamic random access memory (DRAM)/static RAM (SRAM) technology suitable for a high-speed operation. For example, when the memory of the present disclosure replaces SRAM, the capacity of a cache memory may be increased with high integration. Also, when the memory of the present disclosure replaces DRAM, a refresh cycle may be reduced through fast read speed and long retention time, and thereby, a chip operation speed increases and efficient energy use may be achieved. When the memory of the present disclosure replaces both SRAM and DRAM, it is possible to implement a system that does not experience overhead for main memory data fetch from cache memory, and thus, both energy and speed may be increased.

Second, the memory of the present disclosure may be applied to analog computing-in-memory (CiM) which goes beyond limitations of the Von-Neumann computing method. In particular, when a multi-bit operation is implemented by using a wide memory window of the memory according to the present disclosure, the memory may also be applied to CiM macro that may implements both positive weight cells and negative weight cells.

The above descriptions of the present disclosure are for illustrative purposes only, and those skilled in the art to which the present disclosure belongs will understand that the present disclosure may be easily modified into another specific form without changing the technical idea or essential features of the present disclosure. Therefore, the embodiments described above should be understood as illustrative in all respects and not limiting. For example, each component described as a single type may be implemented in a distributed manner, and similarly, components described in a distributed manner may also be implemented in a combined form.

The scope of the present disclosure is indicated by the following claims rather than the detailed description above, and the meaning and scope of the claims and all changes or modifications derived from the equivalent concepts should be interpreted as being included in the scope of the present disclosure.

### BRIEF DESCRIPTION OF THE SIGNS

10: memory
110: gate
120: drain contact
130: source contact
140: gate contact
150: ferroelectric layer

What is claimed is:

1. A memory using ferroelectric metal field-effect transistors, the memory comprising:
a drain, a source, and a gate formed on a substrate;
a gate contact formed on an upper portion of the gate; and
a ferroelectric layer disposed between the gate contact and the gate and configured to surround the gate contact,
wherein the gate, the ferroelectric layer, and the gate contact operate as a capacitor having a metal-ferroelectric layer-metal (MFM) structure.

2. The memory of claim 1, wherein
the gate extends in a longitudinal direction, and
the gate contact extends in a depth direction from an upper portion of one end of the gate toward the gate.

3. The memory of claim 2, wherein
an area in which the gate overlaps the gate contact changes depending on a depth in which the gate contact extends toward the gate.

4. The memory of claim 1, wherein
each of the ferroelectric metal field effect transistors includes any one of planar field effect transistor (FET), a FinFET, a gate all around (GAA)-FET, a nanosheet (NS)-FET, a nanowire (NW)-FET, or a negative capacitance (NC)-FET.

5. The memory of claim 1, wherein
the gate contact and the ferroelectric layer are formed in a front-end-of-line (FEOL) process.

6. The memory of claim 1, wherein
the ferroelectric layer is formed of one of HZO, HfO₂ doped with Al, HfO₂ doped with Si, HfO₂, BaTiO₃, or PbTiO₃.

7. A method of fabricating a memory using a ferroelectric metal field effect transistor, the method comprising:
forming a drain, a source, and a gate on a substrate;
forming a gate contact region on an upper portion of the gate; and
sequentially forming a ferroelectric layer and a gate contact in the gate contact region,
wherein the gate, the ferroelectric layer, and the gate contact operate as a capacitor having a metal-ferroelectric layer-metal (MFM) structure.

8. The method of claim 7, wherein the forming of the drain, the source, and the gate includes: forming the gate extending in a longitudinal direction on the substrate, and
wherein the forming of the gate contact region includes forming the gate contact regionto extend in a depth direction from an upper portion of one end of the gate toward the gate through a patterning and etching process.

9. The method of claim 7, wherein the sequentially forming of the ferroelectric layer and the gate contact includes:
stacking the ferroelectric layer along an inner side surface of the gate contact region; and
stacking the gate contact along an inner side surface of the ferroelectric layer.

10. The method of claim 7, wherein the forming of the drain, the source, and the gate to the sequentially forming of the ferroelectric layer and the gate contact are performed in a front-end-of-line (FEOL) process.
